(19) United States
(12) Patent Application Publication
(10) Pub. No.: US 2008/0098805 A1
(43) Pub. Date: May 1, 2008

(54) Nanotube-Based Nanoprobe Structure and Method for Making the Same

(76) Inventors: Sungho Jin, San Diego, CA (US); Ratneshwar Lal, Goleta, CA (US)

Correspondence Address: LEWIS, BRISBOIS, BISGAARD & SMITH LLP, 221 NORTH FIGUEROA STREET, SUITE 1200, LOS ANGELES, CA, 90012, US

(21) Appl. No.: 11/664,009

(22) PCT Filed: Sep. 29, 2005
(86) PCT No.: PCT/US05/34835

§ 371 Date: Sep. 17, 2007

Related U.S. Application Data
(60) Provisional application No. 60/616,948, filed on Oct. 6, 2004.

(51) Int. Cl. B32B 1/00; B05D 5/12; B44C 1/22; C23C 14/06; C23C 8/00

(52) U.S. Cl. 73/105; 204/192.22; 216/11; 427/58; 427/585; 428/98; 977/956

(57) ABSTRACT

An atomic force microscopy (AFM) nanoprobe comprising a nanocone base and a nanoprobe tip wherein the length to base diameter aspect ratio is at least 3 or more. The AFM nanoprobe tip structure comprises an orientation-controlled (vertical or inclined), high-aspect-ratio nanocone structure without catalyst particles, with a tip radius of curvature of at most 20 nm.

### FIELD OF THE INVENTION

The present invention relates to nanoprobes, in particular, atomic force microscopy probes utilizing carbon nanotubes (CNT).

### BACKGROUND OF THE INVENTION

The resolution of atomic force microscopy (AFM) imaging is determined by the sharpness, size and shape of the probe tip; see the following articles by; Rugar, et al, “Atomic force microscopy”, Phys. Today 43(10), 23-30 (1990); Noy, et al, “Chemical force microscopy”, Annu. Rev. Mater. Sci. 27, 381-421 (1997); Hansma, et al, “Biomolecular imaging with the atomic force microscope”, Annu. Rev. Biophys. Biomol. Struct. 23, 115-139 (1994), and Shao, et al, “Progress in high resolution atomic force microscopy in biology”, Quart. Rev. Biophys. 28, 195-251 (1995).

Typical commercially available AFM probe tips are made of silicon or silicon nitride (Si3N4) which is microfabricated into a pyramid configuration. Such probes have a typical tip radius of curvature in the ˜50 nm regime thus exhibiting a limited lateral resolution, and their rigid pyramid shape does not allow easy access to narrow or deep structural features.

Carbon nanotube technology, as to a “thin-probe-on-pyramid” configuration was described in U.S. Pat. No. 6,716,409, “Fabrication of nanotube microscopy tips” issued to Hafner, et al. on Apr. 6, 2004; U.S. Pat. No. 6,401,526, “Carbon nanotubes and methods of fabrication thereof using a liquid phase catalyst precursor” issued to Dai, et al. on Jun. 11, 2002; and in articles by Dai, et al., “Nanotubes as nanoprobes in scanning probe microscopy”, Nature 384, 147-150 (1996); by Colbert, et al, “Growth and sintering of fullerene nanotubes”, Science 266, 1218-1222 (1994); by Wong, et al, “Carbon nanotube tips: High-Resolution probes for imaging biological systems”, J. Am. Chem. Soc. 120, 603-604 (1998); by Nishijima, et al, “Carbon nanotube tips for scanning probe microscopy: preparation by a controlled process and observation of deoxyribonucleic acid”, Appl. Phys. Lett. 74, 4061-4063 (1999); by Stevens, et al, “Carbon nanotubes as probes for atomic force microscopy”, Nanotechnology 11, 1-5 (2000); by Yenilmez, et al, “Wafer scale production of carbon nanotube scanning probe tips for atomic force microscopy”, Appl. Phys. Lett. 80, 2225-2227 (2002); and by Minh, et al, “Selective growth of carbon nanotubes on Si microfabricated tips and application for electron field emitters”, J. Vac. Sci. Technol. B21 (4), 1705-1709 (2003).

According to these prior art descriptions, multiwall carbon nanotubes (MWNTs) with a diameter of ˜5-100 nm, a single wall carbon nanotube (SWNT) (˜1.2 nm diameter), or a bundle of SWNTs (˜10-50 nm diameter) can be attached onto the ends of Si tips, and a deep geometric feature can be imaged. However, with the still relatively large nanotube dimensions utilized so far, the ultimate, potential improvements in lateral resolution were not seriously investigated. The long and slender geometry of carbon nanotubes (high aspect ratio) offers obvious advantages for probing narrow and deep features. The elastically compliant behavior of high aspect ratio nanotubes is also advantageous. Even when the stress encountered by the nanotube probe reaches beyond a critical force, the nanotube can elastically buckle and recover to accommodate the strain, thus limiting the maximum force exerted onto a sample being imaged by the AFM probe. This is particularly advantageous when the samples being examined are mechanically soft or fragile such as in the case of biological surfaces.

In these prior art processes the attachment of a carbon nanotube onto an AFM probe tip is accomplished by several different means, for example, using acrylic adhesives under optical microscope, carbon deposition in a scanning electron microscope (SEM), or electric arc discharge technique. In-situ growth of carbon nanotubes directly on AFM tips were also reported in U.S. patents by Hafner, et al. and Dai el al., and articles by Yenilmez, et al. and by Minh, et al. cited above.

While the attachment or growth of carbon nanotubes on AFM tips has been demonstrated, there are major problems that need to be resolved for practical applications of nanotube-tip AFMs;

i) the reproducibility and reliability in shape, size, and attachment angle of nanotube probes is yet to be established,

ii) the adhesion strength of attached or grown nanotubes on AFM pyramid tips needs to be improved,

iii) the presence of undesirable multiple nanotubes at the probe tip, instead of a desirable single nanotube. This is often seen during the prior art, in-situ chemical vapor deposition (CVD) growth of nanotubes from an AFM pyramid tip, due to the presence of multiple catalyst particles, as it is not easy to place just a single catalyst island at the pyramid apex. The presence of such multiple nanotubes at the probe tip, some of which tangle with each other, is highly undesirable as it complicates the AFM imaging and interpretations.

iv) the attached or in-situ grown nanotubes by prior art processes are often bent, crooked, or at some arbitrary angle from the probe tip, instead of being straight and vertically positioned as is desired for consistency of AFM probes,

v) the small diameter of a nanotube probe makes the probe tip fragile and susceptible to thermal or mechanical vibrations unless the nanotube is made relatively short, and

vi) the side wall (outside wall) of the conductive nanotube needs to be electrically insulated in order to efficiently utilize the CNT-AFM probes for nanoscale electrical conductivity measurements. This is especially important for high-resolution, multi-functional AFM analysis such as conduction AFM analyses of bio functions, e.g., the Ca++ ion conductivity measurements to study undesirable nanoscale poration or formation of ion channels in the cell membranes in Alzheimer' disease type, neuro-degenerative problems. See articles by Ionescu-Zaneti, et al., “Simultaneous imaging of ionic conductivity and morphology of a microfluidicfsystem”, J. Appl. Phys. Vol. 93, page 10134-10136 (2003); and by Proksch, et al., “Imaging the internal and external pore structure of membranes in fluid: Tapping mode scanning ion conductance microscopy”, J. Biophys. Vol. 71, page 2155-2157 (1996). For these applications, it is essential that the electrical current flows mostly from the very tip of the nanotube probe to the targeted nanoscale location on the sample surface being probed, so that the diversion of current from the side wall of the nanotube is minimized.

This invention discloses novel, conductive probe tip structures and methods for realizing such structures in order to resolve or mitigate various problems associated with prior art, nanotube based AFM probes described above. In this invention, the atomic force microscopy is broadly defined as the analysis of metrology for surface topography, as well as other analyses such as the conductance analysis, dry or wet environment metrology or conductance analysis, mechanical property analysis of the small or surface features, capacitance measurements, field emission measurement, work function measurements, magnetic force measurements, as well as use of probes for sidewall metrology and physical property measurements.

### SUMMARY OF THE INVENTION

Carbon nanotubes are one of the most exciting new nanomaterials, which have received much attention in recent years because of interesting scientific phenomena associated with such a fine, one-dimensional material. The carbon nanotubes are composed of cylindrically arranged graphitic sheets with diameters in the range of ˜1-50 nm and length/diameter aspect ratios greater than 1,000. Carbon nanotubes can now be grown in the form of well aligned and oriented fibers on a substrate using chemical vapor deposition (CVD) such as microwave plasma CVD or DC plasma CVD. See articles by Ren, et al., “Synthesis of large arrays of well-aligned carbon nanotubes on glass”, Science 282, page 1105 (1998); by Bower, et al., “Plasma-induced alignment of carbon nanotubes”, Appl. Phys. Lett., 77, 830-832 (2000), and “Nucleation and growth of carbon nanotubes by microwave plasma chemical vapor deposition”, Appl. Phys. Lett., 77, 2767-2769 (2000); and by Merkulov, et al., “Alignment Mechanism of Carbon Nanofibers Produced by Plasma-Enhanced Chemical-Vapor Deposition”. Appl. Phys. Lett. 79, 2970-2972 (2001).

The growth direction of nanotubes can also be altered in the middle of the CVD growth by using intentionally applied electric field, on the order of several hundred volts. See Aubuchon et al, “Multiple Sharp Bending of Carbon Nanotubes during Growth to Produce Zig-Zag Morphology” Nano Lett. Vol. 4, page 1781-1784 (2004). By altering the electric field direction from the recessed corner of conductor plates, the nanotube growth direction can be sharply re-directed to any desired new direction.

The diameter of carbon nanotubes is also an important parameter that has significant implications to the properties and applications of nanotubes to AFM metrology applications. It is well known that nanotubes with smaller diameter can be obtained by reducing the catalyst island size for CVD deposition (e.g., by nanoscale patterning such as electron-beam or optical lithography patterning, or by use of pre-made nanoscale catalyst particles. Typical catalyst materials for nanotube growth include Ni, Co, Fe or their alloys.

In this invention, in order to solve the problem of prior art nanotube AFM tips, such as poor adhesion onto AFM pyramid, non-straightness of nanotubes, insufficient tip sharpness, and the non-vertical alignment, three embodiments of a novel type of nanotube configurations are disclosed and claimed herein.

### BRIEF DESCRIPTION OF THE DRAWINGS

The nature, advantages and various additional features of the invention will appear more fully upon consideration of the illustrative embodiments now to be described in detail with the accompanying drawings. In the drawings:

FIGS. 1(a) and (b) represent scanning electron microscope (SEM) pictures of (a) an aligned carbon nanotube structure, (b) an aligned nanocone structure.

FIGS. 2(a)-(c) schematically illustrate a processing step of fabricating a nanocone AFM probe structure, and

FIG. 2(d) illustrates an alternative configuration showing an inclined nanocone probe tip according to the invention.

FIG. 3 is an SEM micrograph of an array of carbon nanocone probe tips obtained by patterning of Ni catalyst followed by Electric field oriented CVD growth.

FIGS. 4(a) and (b) schematically illustrate an insulating film coated nanocone AFM probe structure according to the invention.

FIGS. 5(a) to (e) schematically illustrate a sequence of processing steps to prepare an AFM probe tip structure comprising a bent and well adhered nanotube.

FIG. 6 schematically illustrates a bent nanotube attached onto one or more AFM pyramid tips.

FIGS. 7(a) and (b) represent SEM micrographs showing (a) slightly but sharply bent nanotube, (b) 90 degree bent nanotube, obtained by CVD under applied electric field in the recessed edge area of contacting conductor plates.

FIGS. 8(a) and (b) schematically illustrate processing steps of obtaining a nanotube-nanocone bent AFM probe tip structure according to the invention.

FIGS. 9(a) to (d) schematically illustrate processing steps of obtaining a bent nanocone AFM probe tip structure according to this invention.

FIGS. 10(a) to (c) represent schematic drawings and FIGS. 10(a′) to (c′) the SEM micrographs showing the two-step growth processing steps of obtaining the inventive vertically hierarchic nanotube AFM probe structure.

FIGS. 10(d)-(g) schematically illustrate variations of the hierarchic nanocone probe structure.

FIGS. 11(a) and (b) show (a) a SEM photo of nanocone array (b) a two-stage, vertically hierarchic, nanotube based AFM probe array.

FIGS. 12(a) to (c) describe fabrication of single nanotube probe tip on an AFM apex using a multilayer thin film deposition and tip exposure.

FIGS. 13(a) to (d) schematically illustrate a method of placing a single catalyst by dip coating and thermal decomposition for a single nanotube deposition on AFM apex.

FIGS. 14(a) to (c) illustrate selected removal of insulator from an AFM tip by mechanical abrasion or localized acid etching.

FIGS. 15(a) and (b) schematically illustrate a method of oblique incident deposition of an insulating layer on as nanotube sidewall without covering the nanotube tip.

FIG. 16 schematically illustrates an AFM probe according to the invention which is capable of performing surface measurement functions. It is to be understood that the drawings are for purposes of illustrating the concepts of the invention and are not to scale.

### DETAILED DESCRIPTION OF THE INVENTION

### (1) High Aspect-Ratio Nanocone-Shaped Nanotube AFM Tip

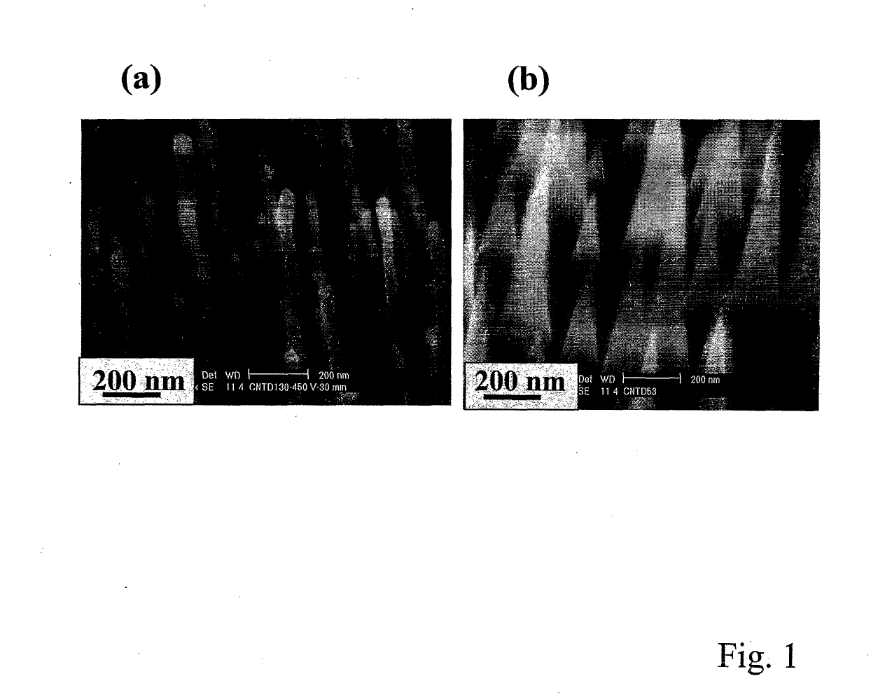

One way of making the nanotube tip less fragile is, according to this invention, to make the nanotube tapered into a nanocone geometry. The desirable configuration is to provide a very sharp tip for high resolution AFM imaging, e.g., the tip radius of curvature of at most 15 nm, preferably 5 nm or less, and even more preferably 2 nm or less. For the purpose of mechanical sturdiness of the nanotube probe in the absense of an AFM pyramid base structure, the cone structure needs to have a substantial base cone diameter. The desirable cone base diameter is at least 100 nm, preferably at least 300 nm, even more preferably 500 nm. To simultaneously provide a small-diameter, sharp tip for high resolution AFM analysis and mechanical stability with a large diameter cone base, a certain minimal high aspect ratio of the nanocone structure is desirable. For example, the ratio of the nanocone length/cone base diameter in this invention is at least 3, preferably at least 5, even more preferably at least 10. Such a high aspect ratio of nanocone probe tip is also beneficial in probing shallow crevices or narrow tracks. A prior art nanotube structure grown vertically aligned using DC plasma CVD process is shown in FIG. 1(a) as a scanning electron microscope (SEM) image. The vertical alignment morphology of nanotubes such as shown in FIG. 1(a) is obtained after growth by DC plasma CVD using a mixed gas of acetylene and ammonia at ˜700° C. at an applied voltage of ˜450 volts or lower at a cathode-anode gap of about 1 cm. These carbon nanotubes are multiwall nanotubes (MWNTs) having a diameter typically in the range of ˜5-100 nm depending on how many walls (concentric cylinders) are present in the nanotube. Alternatively, the graphene walls in the inventive carbon nanocones or nanotubes can be of herring bone type, i.e., the graphene walls can have certain inclined angle relatively to the axis of the nanotube or nanocone.

Shown in FIG. 1(b) is a microstructure consisting of aligned carbon nanocones instead of nanotubes, which is obtained by identical DC plasma CVD processing as in FIG. 1(a) but at a higher applied voltage of ˜500 volts or higher. The nanocones are very sharp at the tip with an estimated radius of curvature as small as a few nanometers or even less.

The prior art type aligned nanotubes, such as shown in FIG. 1(a), have a finite and much larger diameter tip (e.g., 20-40 nm radius of curvature) because of the more or less spherical Ni catalyst nanoparticles present at the tip. In the inventive nanocone structure of FIG. 1(b), the catalyst particles are absent as they are sputter etched in the plasma environment during CVD, and a very sharp tip is achieved. In this invention, the term “nanocone” is also called a “nanocone nanotube”, as some of the nanocones are partially or wholly tube-like while other nanocones are mostly solid. The nanocones are made of carbon but contain some silicon (e.g., 2-50 wt %) depending on the CVD conditions. The silicon is incorporated into the nanocones by either the diffusion of Si from the substrate material or by sputter etching of Si from the substrate and its trapping in the nanocone as carbon is added onto the nanocone.

The growth of nanocone is facilitated, according to this invention, by utilizing a higher applied voltage in the plasma CVD process so that the sputter erosion of Ni catalyst particle gradually occurs at the optimal rate during nanotube growth and induces a gradual decrease in catalyst capacity for carbon uptake occurs, which results in a slow down of nanotube height increase. Simultaneous with the decreased rate of height increase, carbon and silicon are added onto the sidewall of nanotubes, thus forming the nanocone geometry.

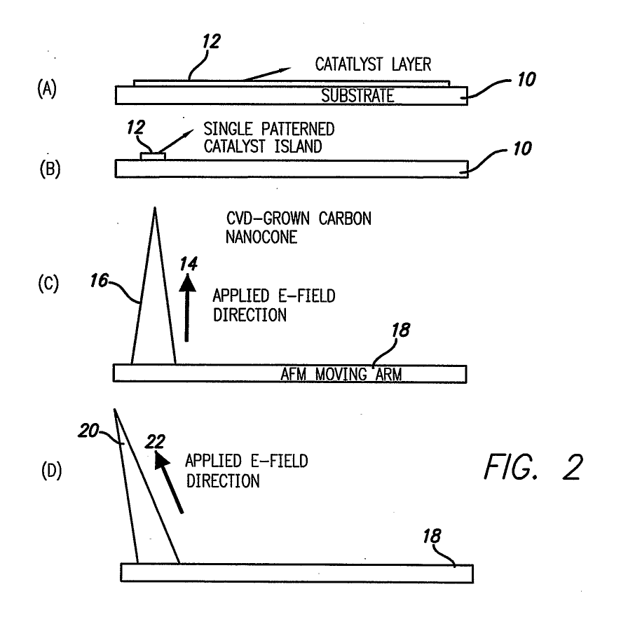

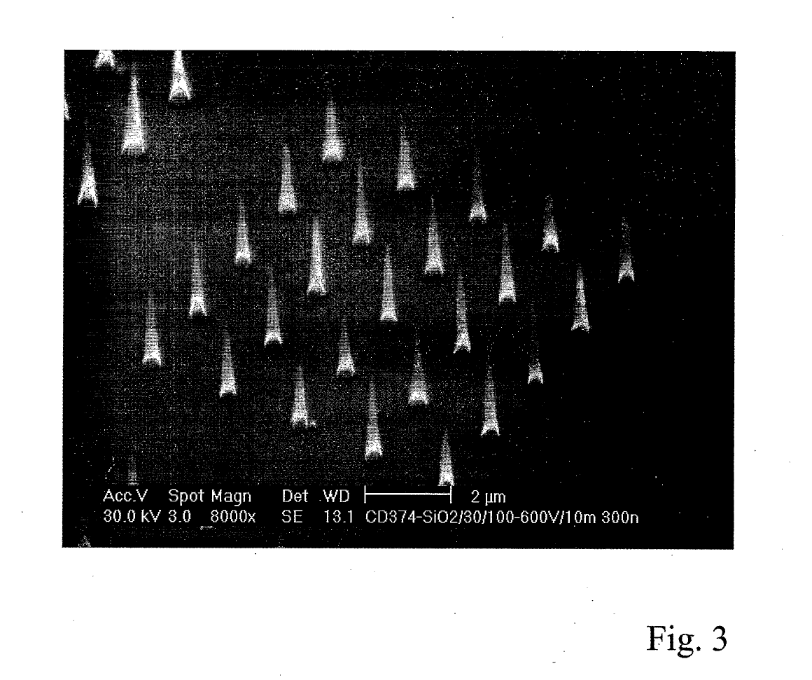

FIG. 2 schematically illustrates an exemplary fabrication process for preparing the nanocone-tipped AFM probe. On a substrate 10, such as Si, Si-nitride, Si-oxide, GaAs, GaN, and various other cantilevers, an island of catalyst is placed, e.g., by deposition of catalyst layer 12 (e.g., 2-20 nm thick layer of Ni, Co, Fe or their alloys), FIG. 2(a), which is lithographically patterned as a single island of e.g., 50-500 nm diameter, FIG. 2(b). A DC plasma CVD processing, e.g., using acetylene and ammonia gas mixture at an applied voltage of 400-800 volts and a temperature of 500-1000° C., is employed to grow the nanocone structure with a right aspect ratio and tip sharpness. A preferred voltage to be applied for preparation of the nanocone suitable for an AFM probe tip is at least 470 volts, preferably at least 500 volts, even more preferably at least 550 volts. In terms of the average applied electric field, the applied voltage divided by the gap distance between the cathode (i.e., the substrate surface) and the anode (by which the voltage is applied), the desired average field to induce the inventive process of gradual sputter erosion of the catalyst particle and eventual complete removal of the particle to induce the very sharp nanocone probe tip, is at least 300 volts/cm, preferably at least 400 volts/cm, even more preferably at least 500 volts/cm. According to the another aspect of the invention, the nanocone growth direction is controlled by altering the direction of the applied electric field during the CVD growth process. When the applied electric field is beyond a certain critical value, the catalyst particles at the nanotube tips are sputter etched away, and the typical, equi-diameter nanotube shape is then transformed to a nanocone configuration with no catalyst particles remaining at the tip. For a vertically oriented applied electric field 14, the nanocone 16 grows along the vertical direction, FIG. 2(c). The substrate 10 of FIG. 2(b), if many, spaced apart catalyst islands are fabricated on it, can be cut into many identical pieces with each of them used for subsequent nanocone growth, or alternatively, the CVD nanocone growth can be performed first on a wafer containing many similar, spaced-apart catalyst islands followed by cutting into many identical pieces for use as individual AFM arm structures 18 as shown by an example in FIG. 3. For an inclined nanocone position 20 as in FIG. 2(d), which is sometimes desired if the positioning angle of the AFM arm itself is tilted in AFM operation, the nanocone growth is made to occur along an inclined direction by carrying out the CVD growth in such a way that the nanocone grows following a locally inclined electric field direction 22. On operation of the AFM cantilever arm which itself is tilted, such an inclined orientation of carbon nanocone compensates the angle so as to provide a more or less vertical nanoprobe tip positioning relative to the material surface to be probed.

An important aspect of the invention is how to accurately control the direction of the nanocone growth. The control of the electric field direction in a plasma environment is difficult. No matter which way the physical direction of the mating electrodes is arranged, such a physically dictated field direction is more or less ignored and the plasma tends to dictate the local electric field direction on the sample surface due to the self-bias potential, see a book by B. Chapman, Glow Discharge Processes (Wiley, New York, 1980). As the simple inclined field direction cannot produce a tilted nanotube or nanocone growth, due to the tendency of field lines always intersecting perpendicular to the local surface, the desired inclined field is most efficiently obtained by utilizing the electric field present at a recessed edge or corner of intersecting conductor plates. Although there is a naturally occurring inclined electric field enamating from the protruding edges or corners of a conductor block in the presence of vertically applied voltage, such an edge- or corner-field varies considerably in direction as well as intensity with even a slight shift in location, and thus it is difficult to use for reproducibly in preparing the inventive, inclined nanocone structure in a reproducible manner. While the use of such an electric field from conductor edges or corners is not excluded in this invention, the preferred mode of preparing a tilted nanocone structure, is the utilization of the tilted local-surface electric fields from the recessed edges or recessed corners of the conductor plates in contact. Therefore, the desired technique for accurate control of electric field direction in this invention is to use such an inner corner electric field, where the cantilever substrate is placed, as this processing approach allows an accurate control of growth direction of nanocones or nanotubes, both straight and bent configurations.

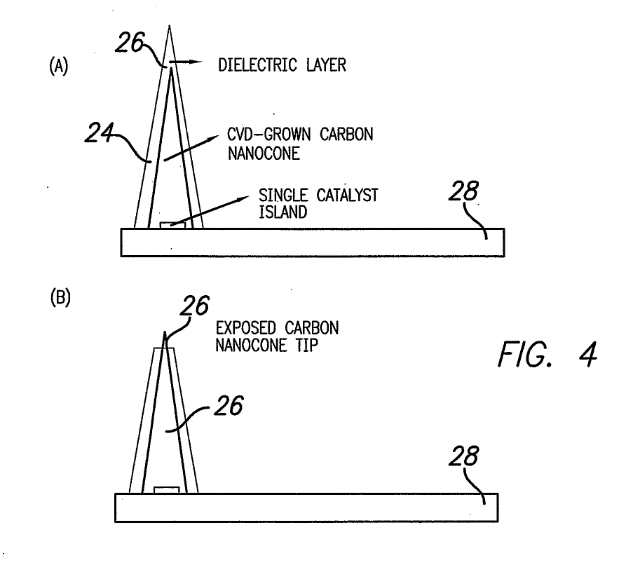

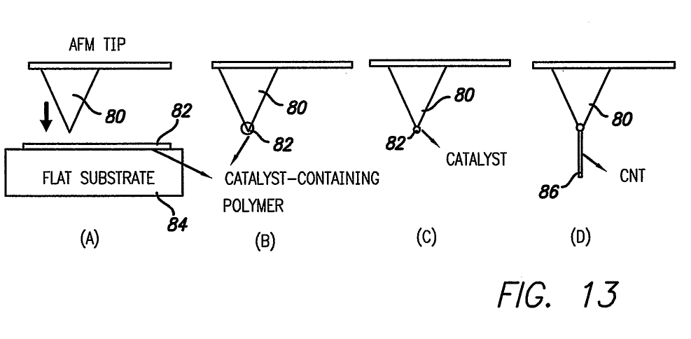

Referring to the schematically illustrated drawing of FIG. 4, another embodiment of the nanocone based AFM probe tip is disclosed. Such an embodiment is especially useful for conductance AFM measurements, in which, not only the metrology but nanocale or microscale electrical transport behavior is also measured, for example for a study of Ca++ ion conductance near the ion channels in a human cell membrane affected by Alzheimer's disease. For desirable electrical isolation, the outer surface of the nanocone 24 is coated with an electrically insulating material, e.g., a polymer or a dielectric oxide such as aluminum oxide, magnesium oxide, silicon oxide or silicon nitride as illustrated in FIG. 4(a). Only the nanocone tip 26 is then exposed, as illustrated in FIG. 4(b), so as to make sure that only the tip 26 is electrically active and participating in the measurement or operation of electrical transport (electrons or ions) with the AFM conductance probe 28 without undesirable divergence of current from the side of the nanocone probe 24. The techniques for preparing the structures of FIG. 4(a) and (b) can utilize one or more of the inventive processes described later in FIGS. 13-15.

The orientation-controlled, high-aspect-ratio nanocone structure is advantageous in producing a high spatial resolution in AFM type probe applications because of the gradual removal of round-shaped catalyst particles from the tip of the nanotube during the high electric field processing and resultant tip sharpness, according to the invention. The desired tip radius of curvature in the inventive, orientation-controlled, high-aspect-ratio nanocone structure is at most 20 nm, preferably at most 10 nm, even more preferably at most 5 nm. The desired nanocone aspect ratio is at least 3, preferably at least 5, even more preferably at least 10. Such a high-aspect-ratio, sharp nanocone probe tip can thus provide even sharper AFM metrology images or conductance measurements as is beneficial for higher resolution analysis and for probing shallow crevices or narrow tracks, and yet the probe base is mechanically much more stable than the standard, uniform-diameter nanotube probes.

### (2) Bent Nanotube AFM Tip

In another embodiment of the invention, the AFM pyramid structure is utilized but is improved with a nanotube or nanocone probe tip which is attached to near the pyramid apex by either physical bonding such as arc welding, adhesive or solder/braze bonding, or localized graphite deposition using a localized electron-beam in a scanning electron microscope environment. Two of the frequently encountered problems in the physically bonded nanotube probe are the instability of the shape and the attachment angle of the nanotube probe, and the relatively poor adhesion strength of attached nanotubes on the AFM pyramid tip. Such a mechanical instability can lead to undesirable changes in the nanotube shape and projected length caused by permanent bending or rotation near the bond area, or even a detachment of the nanotube tip from the pyramid base due to the frictional or electrostatic force encountered during AFM operation. In the following description of another embodiment of this invention, a nanotube arrangement structure with improved mechanical stability and desirable probe orientation is disclosed. The processing methods to produce such desirable structures are also disclosed.

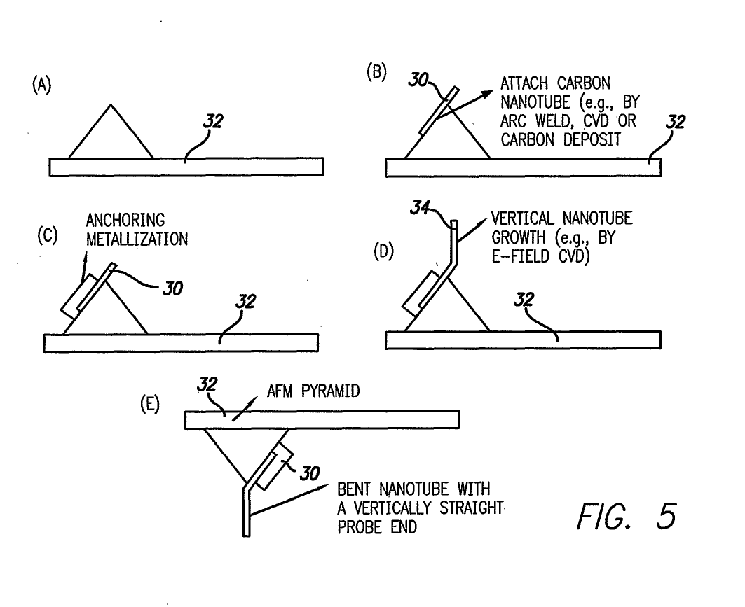

The prior art, as-attached nanotube configuration 30, such as is illustrated in FIG. 5(b), produces not only relatively poor adhesion on a pyramid base, but a nanotube orientation at some arbitrary angle from the probe tip, depending on how each arc welding operation is carried out each time, with a different nanotube. The orientation of the attached nanotube is thus basically unpredictable. For reliable operation of AFM analysis, the probe tip, such as the attached nanotube end, should have a predictable orientation, preferably being straight and vertically positioned as is desired for consistency of AFM probes, instead of being confined to the given pyramid slanting angle. In the inventive nanotube-on-pyramid structure, the adhesion and hence the mechanical stability of the attached nanotube is enhanced by a deposition of an anchoring thin film as illustrated in FIG. 5(c).

The desired thin film material is preferably selected from carbide-forming metals or alloys which tend to form carbides easily and thus chemically bond easily on a carbon nanotube surface. Such metals include Cr, Ti, Si, Mo, Zr, Hf, Nb, Ta, W, or their alloys. These metals also tend to adhere well on Si, Si-oxide or Si-nitride material which is often the base material of the AFM pyramid. The nanotube-bonded structure can optionally be given an annealing heat treatment (e.g., 300-800° C. for 10 minutes to 24 hrs) so as to relieve residual stress in the deposited film and carbon nanotube, as well as to induce more chemical bonding between the metal film and the attached carbon nanotube, and also between the film and the pyramid surface. Alternatively, an electrically insulating compound such as selected from oxides or nitrides (e.g., Si oxide, Si nitride, Ti oxide, Al oxide, Al nitride) can be utilized as the anchoring film, especially if the electrical isolation of the nanotube probe surface is desired. In this case, the surface of the pyramid base is already conductorized by metallic coating prior to this anchoring film deposition.

The anchoring film can be depositied by sputtering, evaporation, or CVD deposition. Substrate rotation is optionally desired to make the distribution of stress by the film deposition more uniform. The desired thickness of the anchoring film is in the range of 1-200 nm, preferably in the range of 10-50 nm so that there is a sufficient amount of anchoring film material present yet it is not too thick to cause stresses on nanotubes.

The next step in fabricating the inventive, stable, and convenient nanotube-on-pyramid structure is to grow an entirely new segment of a nanotube (or a nanocone) on existing, attached nanotube of FIG. 5(d). The first segment of the nanotube 30 (FIG. 5(b)), when it is attached onto the AFM pyramid 32, is positioned in such a way that the nanotube-nucleating catalyst nanoparticle (such as Ni, Fe or Co) is present at the upper end of the nanotube in FIG. 5(b) or FIG. 5(c). Utilizing the catalyst particle at the end of the the attached nanotube, e.g., arc welded nanotube, the AFM pyramid with the firmly attached nanotube 30, FIG. 5(c), is then placed in a CVD chamber and is subjected to a nanotube CVD growth process again. Because the only catalyst particle available is the one at the attached nanotube end, a continued growth of a nanotube will occur. In the inventive process, the nanotube growth orientation is re-directed by applying an electric field, for example along the desired vertical direction 34 as illustrated in FIG. 5(d). The finished pyramid tip with a nanotube with a desirable pointing angle and bond strength is then connected to an AFM or STM system, FIG. 5(e), for metrology or conduction AFM measurements. Of course a variation of this processing is to get the CVD condition modified toward a higher applied voltage in such a way that the nanotube grows into a nanocone with resultant sharper tip dimension.

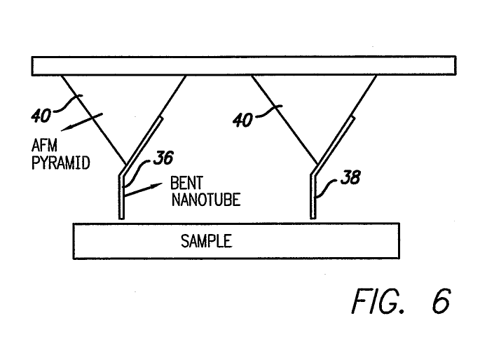

Alternatively, pre-made bent nanotubes 36, 38 can be detached from the substrate, and then attached onto the AFM pyramid sidewall 40 as illustrated in the drawing of FIG. 6, e.g., by using an attachment technique such as arc welding, carbon deposition, soldering/brazing and other approaches. An adhesion-enhancing film can be applied to this structure similarly as in the case of FIG. 5.

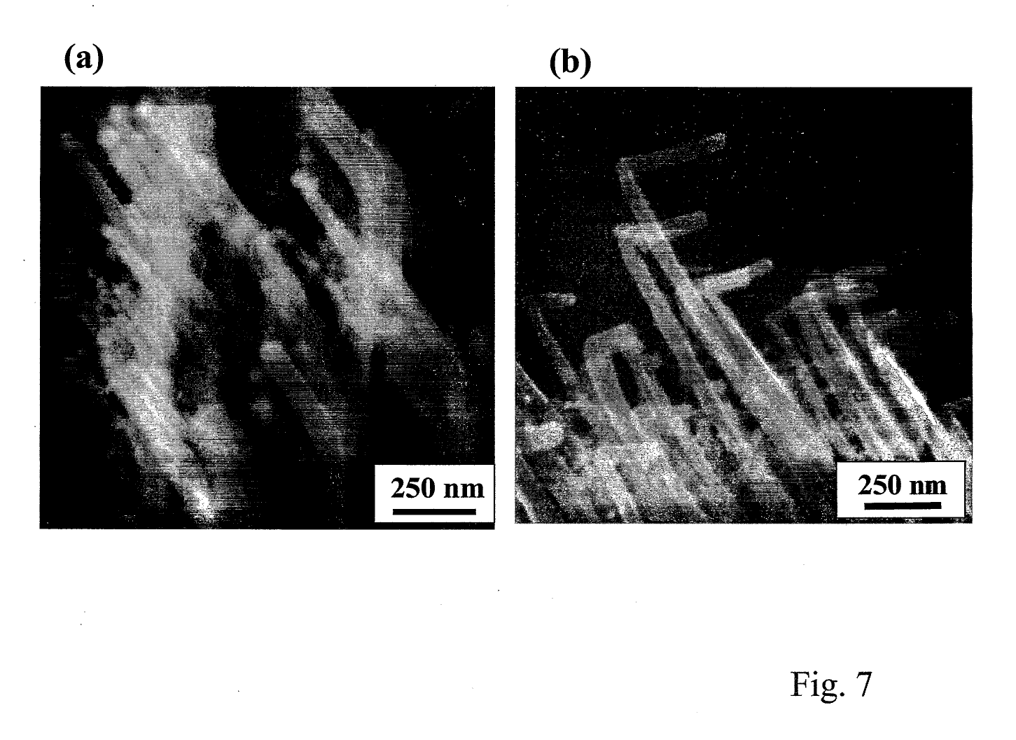

Such a desired sharp bending of nanotube growth direction is obtained by a unique use of electric field. A well-defined, sharp bending with a bending radius of curvature of less than 100 nm, preferably less than 40 nm is obtained by CVD processing in the presence of a recessed-corner electric field. Exemplary sharp bending of the nanotube probe obtained according to the inventive processing is shown in FIG. 7(a) with a sharp and sudden tilting of nanotubes and FIG. 7(b) with a sharp 90° bending obtained with a recessed-corner electric field.

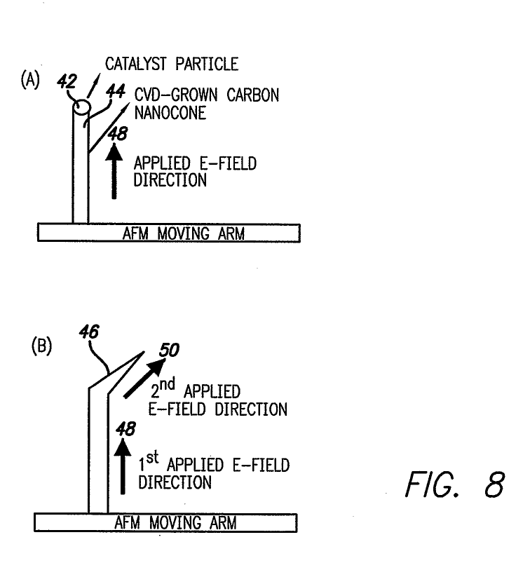

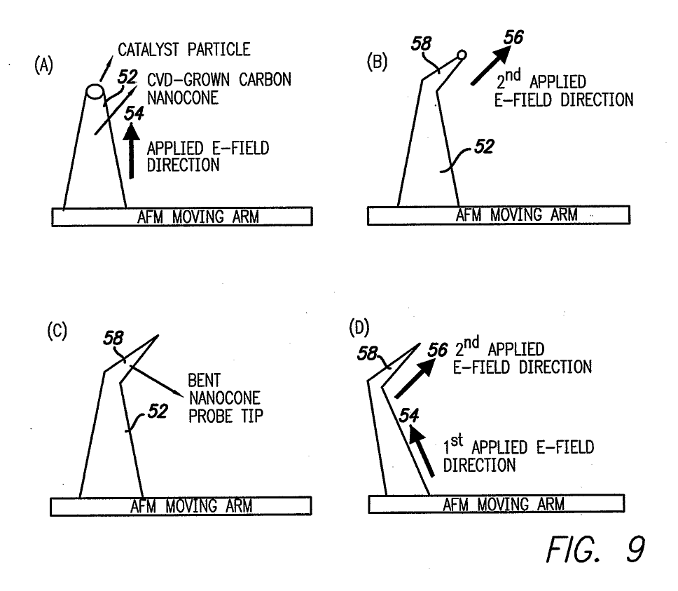

Alternatively, instead of using the conventional AFM pyramid as the AFM probe base, one can use a carbon nanotube as the base structure as well. Onto the tip 42 of this first-leg nanotube 44 which serves as the pyramid-like basis, another nanotube 46 (a second-leg nanotube) is nucleated and grown. Such a duel structure is fabricated as illustrated in FIG. 8. The carbon nanotube is allowed to grow vertically to a desired height, then the growth is interrupted so as to alter the applied electric field 48, 50 orientation and abruptly change the nanotube growth direction. Instead of a nanotube base, a nanocone base can be utilized as this provides more mechanicaql stability of the base as in the case of typical AFM pyramid. As shown in FIG. 9(a)-(c), a nanocone growth orientation, after a certain nanocone height is reached, is abruptly altered by a change of electric field orientation, 54, 56 e.g., using an electric field in the recessed corner of conductor plates where they meet. The base nanocone can also be grown at a certain tilted angle 58 if desired, instead of the vertical direction used during the first leg of the CVD processing sequence, as illustrated in FIG. 9(d).

### (3) Two-Stage Hierarchic Nanotube AFM Tip

Yet another embodiment of nanotube based AFM probe geometry is based on a two-stage, vertically hierarchic, nanotube configuration which uses the nanocone as the basis but using a smaller diameter nanotube as the secondary, sharper leg of the probe structure. The design and fabrication approaches for such a hierarchic nanotube-based probe structure are described below.

### 1. Two-Step CVD Approach

As discussed above, the geometry of the carbon nanotubes depends much on specifics of CVD processing. For example, a higher electric field applied during DC plasma CVD processing tends to induce more cone-like nanotube morphology as compared to the straight, wire-like nanotube structure. The alteration of source hydrocarbon gas composition (toward acetylene-rich chemistry) also helps to induce more nanocone structure. Transmission electron microscopy (TEM) analysis of the carbon nanocone structure indicates that a significant amount of Si became incorporated into the cone structure, implying a possibility of Si diffusion or sputter deposition from the substrate.

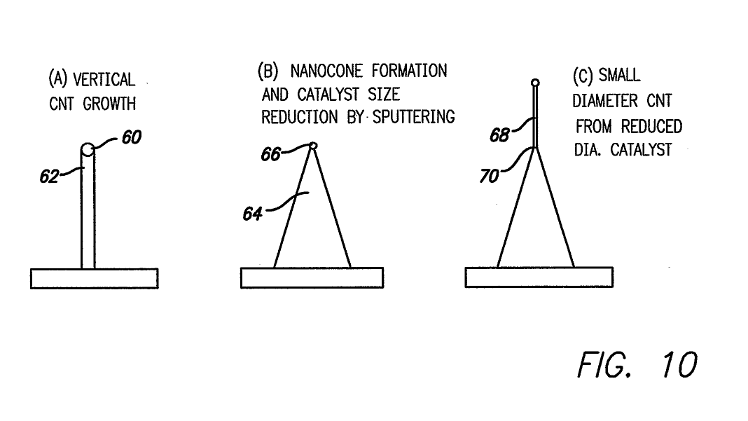

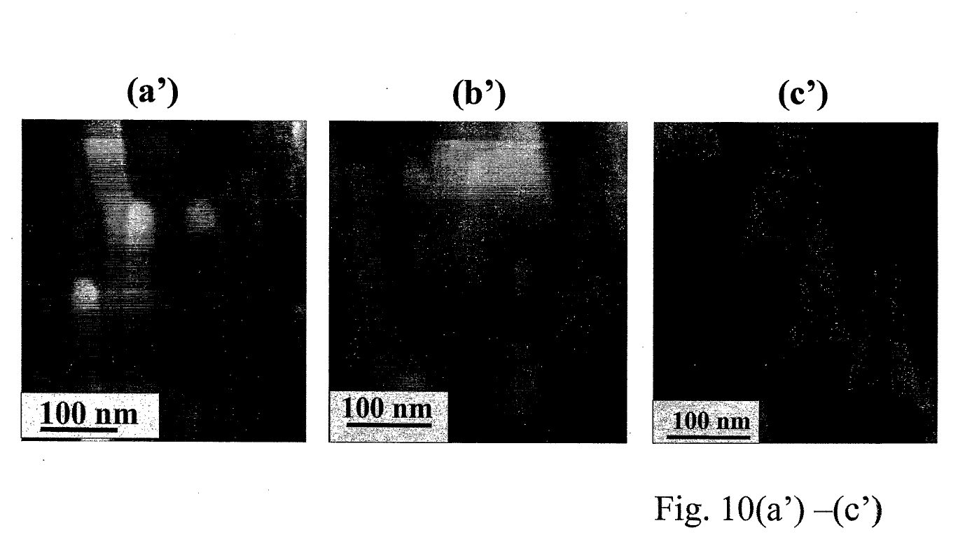

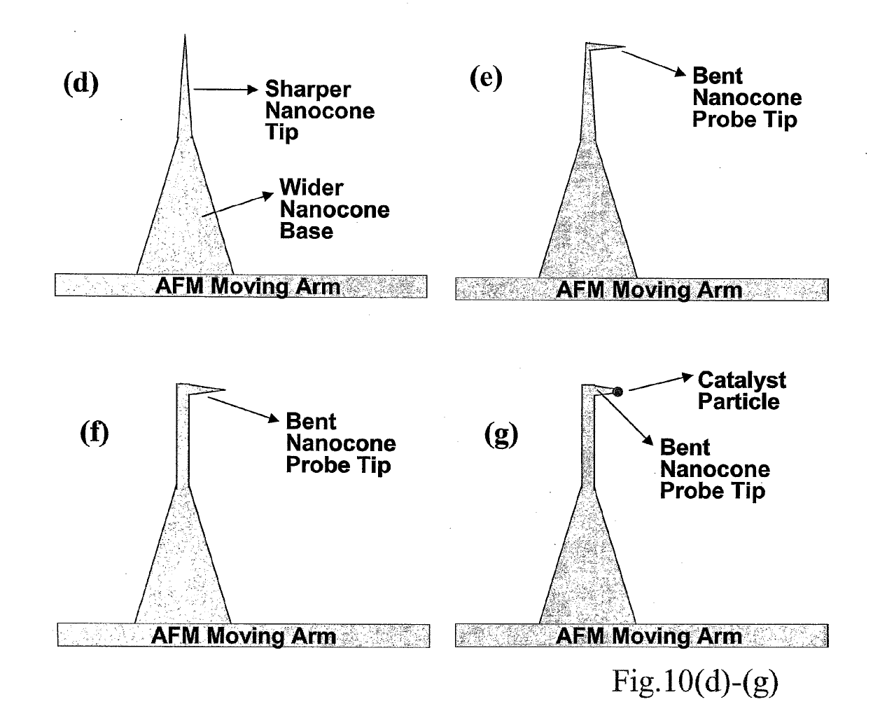

hile the nanotubes or nanocones continue to grow during the CVD process, the presence of DC plasma also causes continuous sputtering erosion of the catalyst particles at the nanotube, gradually making the particle size smaller. As shown in the schematic drawing FIG. 10(a) and the SEM micrograph of FIG. 10(a′), the Ni catalyst particle 60 at the nanotube tip 62, 64 is ˜30 nm in diameter. On continued CVD, the catalyst particle size 66 gets reduced to a much smaller size, e.g., ˜7-10 nm as shown in FIG. 10(b). Such a gradually decreasing catalyst size is partially responsible for the nanocone formation, as the kinetics of carbon uptake at the nanotube tip would become that much slower. By intentionally switching to a lower applied electric field at this stage, and continuing on with CVD, a nanotube 68 with a completely different geometry is now grown from the nanocone tip 70. The reduced size catalyst particles of FIG. 10(b) produces substantially straight and vertically aligned CNTs at the top of the nanocones, with a much reduced diameter of ˜7-10 nm as shown in FIGS. 10(c) and 10(c′), thus resulting in a two-stage, hierarchic, nanotube probe configuration.

Such a two-stage probe configuration with a smaller diameter and flexible CNT on top of a mechanical stable cone base structure is highly desirable for enhanced reliability of high resolution CNT-AFM, especially with an assurance of only one nanotube on the tip, in a desirably straight and vertical geometry. In contrast, an attempt to arc weld a nanotube to the AFM pyramid tip or CVD growth of a nanotube from deposited catalyst particles/film near the pyramid tip often results in an undesirable multiple nanotube attachment at the pyramid tip.

According to the invention, various modified configurations of the FIG. 10(c) type probe tip can be accomplished as illustrated in FIG. 10(d)-(g). In FIG. 10(d), the hierarchic structure now consists of two nanocones of different side angle. The desired aspect ratio of the second nanocone is at least 3 times, preferably at least 6 times larger than the first nanocone.

In FIG. 10(e), the FIG. 10(d) configuration is further altered by bending the tip by switching to a field-guided-CVD process as described earlier. The desired range of the tip bending is at least 10 degrees, preferably at least 30 degrees. In FIG. 10(f), the hierarchic structure of FIG. 10(c) is modified with a tip bending.

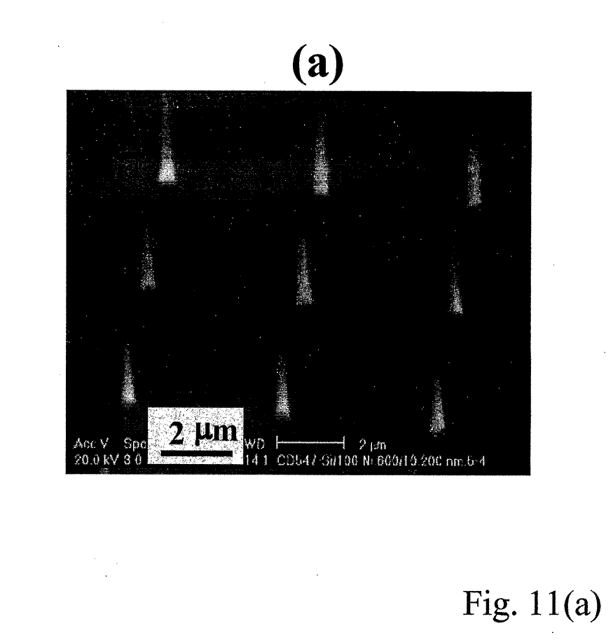

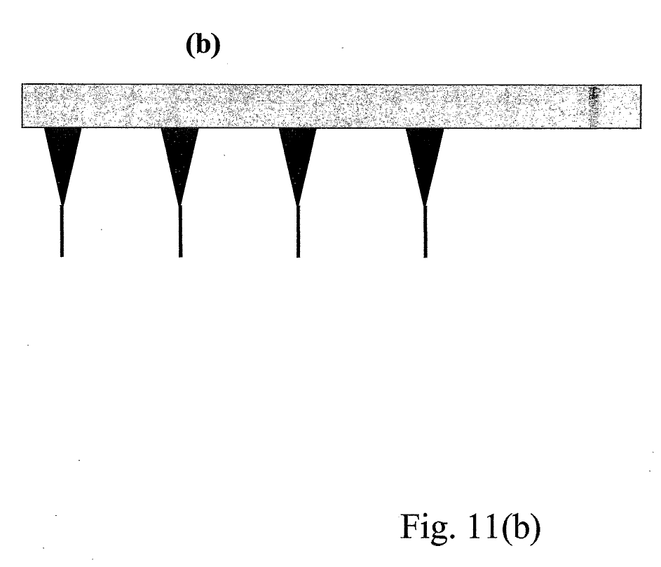

In FIG. 10(g), the catalyst particle at the very tip is left intentionally during the process of FIG. 10(f) by stopping the CVD process prematurely before the complete sputtering away of the catalyst particle. Yet in another variation of the inventive fabrication, an array of such a two-stage probe configuration of FIG. 10(c) is constructed as illustrated in FIG. 11(b), using a patterned and periodic nanocone array structure of FIG. 11(a′) as the basis. Various nano- or micro-patterning techniques such as e-beam patterning, optical patterning or other nonconventional patterning of the catalyst can be used to form the array. Such an array can be used for special applications where a metrology or conductance AFM measurements need to be carried out at multiple locations simultaneously, e.g., in analysis of ion conductance near the cell membrane ion channels, or near the heart cardio activity regions, which can be useful for understanding, drug discovery and possible cure of Alzheimer's disease. Alternatively, such an array structure can be fabricated as a means of mass production, i.e., by dicing the substrate containing the array into individual nanotube probes so that many sets of AFM probe tips can be made from the same wafer.

### 2. Selected CVD Growth of a Single CNT Probe from a Tip-Only-Exposed Catalyst on a Pre-Made, Larger-Size Base

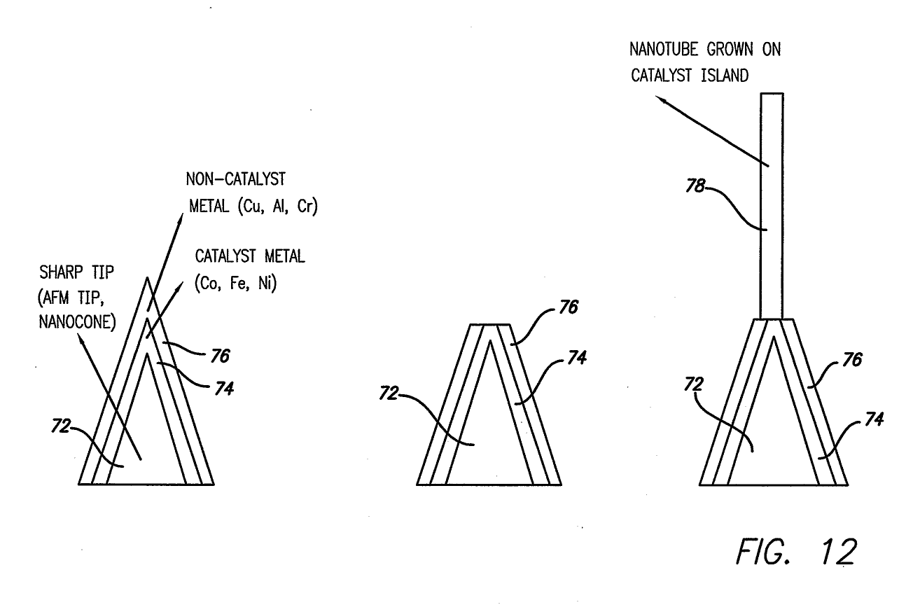

CNTs grow only where the catalyst metal is present. In another variation of the inventive processing to fabricate a two-stage hierarchic nanotube probe structure, a tip-only-exposed catalyst structure, such as illustrated in FIG. 12, is fabricated and utilized in order to force only one, small-diameter CNT to grow from the apex of an Si pyramid. A sharp tip 72 (such as made of Si, Si3O4, tapered metal base, or CNT nanocone described above) is first coated with a catalyst metal 74 (e.g., a few nanometer thick layer of Fe, Co, or Ni or their alloys) by sputtering, evaporation, or chemical/electrochemical means. The next step is to deposit a non-catalyst metal layer 76 (e.g., a few nanometer thick Cu, Mo, Cr, Si) over the catalyst layer as illustrated in FIG. 12(a). The very end of the tip is then mechanically or chemically eroded in a controlled fashion to expose a small island of the catalyst metal, FIG. 12(b). A subsequent CVD growth under applied electric field produce a small diameter CNT as illustrated in FIG. 12(c).

To produce the end-exposed catalyst structure of of FIG. 12(b), a high frequency, mechanical abrasion writing may be utilized to preferentially wear out the mechanically soft outer coating, for example, Cu outer coating would wear out much faster than a Ni alloy or a Co alloy. An alternative process is chemical etching. For example, the tip of FIG. 12(a) may be subjected to a contact scan over the surface of Au-coated aluminum oxide membrane (anodized membrane with vertically aligned nanoscale pores as small as 20 nm in diameter), the pores of which are filled with dilute acid. The contact of the tip end with the acid will dissolve away Cu much faster than Ni, thus exposing a small island of Ni catalyst. An appropriate control of the can time or the degree of acid dilution can be employed to optimize the size of the exposed area.

The catalyst tip exposure in a very small area at the apex of the pyramid or nanocone for nucleation of a single nanotube can be achieved by various other means as well, for example, using plasma etching or focused ion beam (FIB) etching of the dielectric material at the tip.

### 3. Dip Coating and Decomposition Approach

Yet another alternative inventive approach to place a single catalyst nano-island at the apex of the Si AFM tip 80 is to introduce a catalyst-metal-containing polymer liquid 82 as an intermediary process step, followed by decomposition of the polymer to induce a catalyst island at the pyramid apex. This is schematically illustrated in FIG. 13.

As an example, a thin layer of a polymer material (or an adhesive polymer) containing a small atomic % of catalyst in solvent or water (such as Ni-doped polyvinyl alcohol, poly(vinylpyrrolidone) is spin coated on a flat substrate 84, and the AFM pyramid tip (e.g., Si coated with a thin film deposited metal conductor) is then brought down to touch the wet polymer as illustrated in FIG. 13(a). As the tip is lifted off, it is coated with a small droplet of the polymer 82, FIG. 13(b). The dip coated AFM tip 80 will then be pyrolized at 300-600° C. to burn away the polymer and leave only the catalyst metal at the tip, FIG. 13(c). If necessary, additional heat treatment in a reducing atmosphere can be given to ensure that the polymer and other matrix material is completely decomposed or burned away so that the catalyst island is essentially fully metallic. A single and straight carbon nanotube 86 is then grown from this catalyst by CVD processing in the presence of an applied electric field, FIG. 13(d). Since the atomic fraction of the catalyst element in the dip-coated droplet is very small, it is anticipated that the viscosity and size of the droplet can be adjusted to produce a nanoscale catalyst island, which can nucleate either a SWNT or a small diameter MWNT at the apex of the AFM tip.

### 4. Design of Advanced Nanotube-AFM Probe Tip with Nano-Electrical Conductance Measurement Capability

The nanotube-AFM probe is then further modified, according to the invention, to make it more suitable for an advanced, multi-functional probe system, instead of just a higher-resolution metrology AFM for topological imaging. For example, the probe tip can be structured to enable a nanoscale, local conductance electrical measurement in biological systems of interest, such as for studies of electrophysiological behavior of neuronal ion channels under body fluid environment. Important parameters to consider include the electrical properties of the nanotube itself as well as providing electrical isolation of the sidewall of the nanotube probe from surrounding liquid environment.

Carbon nanotubes are in general good electrical conductors. Their electrical resistivity values are of the order of ˜100 micro-ohm·cm at room temperature. See an article by Thess, et al., “Crystalline Ropes of Metallic Carbon Nanotubes”, Science 273, 483 (1996). This is in the same order of magnitue as for graphite. The multiwall nanotubes (MWNTs) exhibit ballistic quantum conductance transport behavior, with enormous current carrying capability of above 107 A/cm2.25. See articles by Frank, et al., Science 280, 1744 (1998), and Avouris, et al., “Carbon nanotubes: nanomechanics, manipulation, and electronic devices”, Applied Surface Science 141, 201-209 (1999). While MWNTs are almost always conductive, SWNTs can be either metallic conductive or semiconductive depending on the chirality of the carbon nanotubes. If a SWNT is to be used as the probe tip for the conductance microscope, it is desirable to make sure that the SWNT is of a conductor type.

The nanocones containing some silicon tend to exhibit somewhat reduced electrical conductivity. An optional probe configuration to impart enhanced electrical conductivity to the probe is to coat the nanocone surface with a thin film of metallic conductors such as transition metals (such as Ni and their alloys), refractory metals (such as tungsten or Mo and their alloys), noble metals (such as Pt and their alloys) by physical or chemical deposition. Instead of metallic coating, conductive carbide (such as tungsten carbide), nitride (such as titanium nitride or tantalum nitride), boride (such as lanthanum boride) or oxide (such as lanthanum strontium manganese oxide or chromium oxide) can also be utilized as these compounds often provide higher wear resistance than metal coatings. The physical deposition can use the process of, for example, sputtering, ion deposition, evaporation, laser ablation, etc. The chemical deposition can use electrodeposition, electroless deposition, chemical vapor deposition, etc. The desired thickness of the conductive film is at least 1 nm. However, for the sake of maintaining the sharpness of the nanocone tip, the coating thickness is maintained to be less than 30 nm, preferably less than 10 nm, even more preferably less than 3 nm.

### 5. Sidewall Insulation of CNT-AFM Probe.

To ensure accurate, nanoscale electrical measurements using the CNT-AFM tip, the sidewall of the CNT needs to be coated with an electrical insulator (dielectric material) so that the measurement current does not diverge or leak in the fluid environment of a biological sample. When the electrical current emanates essentially only from the very tip of the CNT-AFM tip, as is the case of sidewall insulated CNT, the sensitivity and lateral resolution of the electrical measurement will be the highest.

In order to achieve such an insulation, physical or chemical vapor deposition is utilized, or electrochemical/chemical deposition of a thin insulating material on the outside wall of the carbon nanotube already positioned on the apex of AFM tip. For example, RF (radio frequency) deposition of Al2O3, SiO2, Si3N4, TiO2, or plasma CVD deposition of SiO2 is carried out. For uniformity of coating to prevent/minimize CNT bending by stresses, the CNT will be rotated around an axis parallel to the CNT length during the deposition. If a stress is somehow still introduced and the CNT bends, a post-coating, CNT straightening process is utilized, for example, by annealing in the presence of applied electric field which tends to stretch out the nanotube into a straight configuration.

Alternatively, a polymer coating instead of an oxide or nitride coating can also be utilized. There are several different ways of applying a thin polymer coating. One way is to use a naturally occurring monolayer polymer coating. Another is to evaporate deposit a thin layer of polymer, or monomer precursor of a polymer, followed by a low temperature baking to thermally polymerize the coating.

### 6. Selective Removal of Insulator Coating from CNT Tip End

If a conformal process such as CVD or electrochemical deposition method is used for the dielectric coating on a CNT, the CNT tip is covered with the dielectric material. According to the invention, one of the following three alternative processes can be employed to selectively remove the insulator material from the probe tip only.

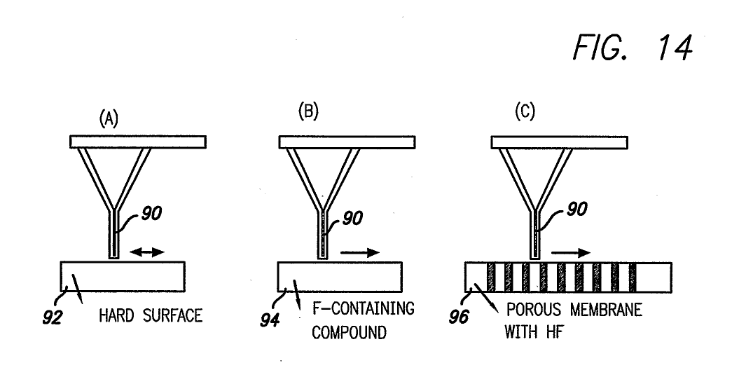

i) high-frequency contact scan of the insulator-coated tip 90 on a solid surface 92 for abrasion wear of the tip insulator (FIG. 14(a)),

ii) low-frequency contact scan on a solid surface 94 and flat chemical compound containing fluorine (such as a plate of NaF, or NH4F, which, in the presence of controlled humidity/moisture, can form HF on the surface and selectively etch SiO2 at the CNT tip that touches the surface, and NH4HF2, which can release HF even without the aid of moisture (FIG. 14(b)), and

iii) contact scan of the tip 90 over the surface of a porous ceramic membrane 96 impregnated with HF solution. For example, the HF solution can be placed in the pores of an anodized alunima membrane with 20-200 nanometer, vertically aligned pores, as illustrated in FIG. 14(c). The pore surface is preferably protected with a noble metal coating (e.g., Au) so that the alumina matrix material is protected from getting attacked/etched by the acid.

### 7. Insulator Deposition with the Nanotube Probe Tip Exposed

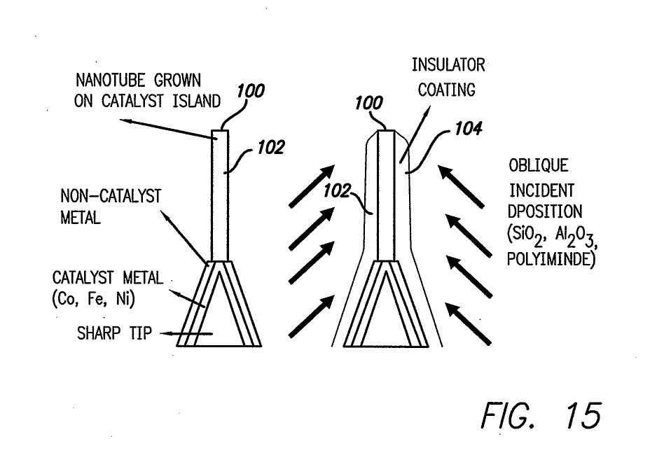

The coating of a CNT sidewall with a dielectric material often results in a coverage of not only the sidewall but the CNT tip as well, which will block or greatly diminish the passage of electrical current from the tip during intended electrical measurements. One of the novel, inventive fabrication approaches to keep the very tip 100 of the CNT 102 probe free of dielectric deposit is to employ an oblique incident deposition of the dielectric material as illustrated schematically in FIG. 15. Because of the shadow effect, the CNT tip 100 can remain mostly uncoated during evaporation deposition of inorganic or polymer coating 104. Sputtering which is less line-of-sight processing, still provides some tip-protection on oblique incident deposition. Either direct insulator deposition, lower oxidation-state oxide (e.g., SiO), or metal deposition of easily-oxidizable elements such as Al, Ti, Si followed by oxidation heat treatment can be used. A polymer or monomer material can also be deposited similarly by the oblique incident evaporation.

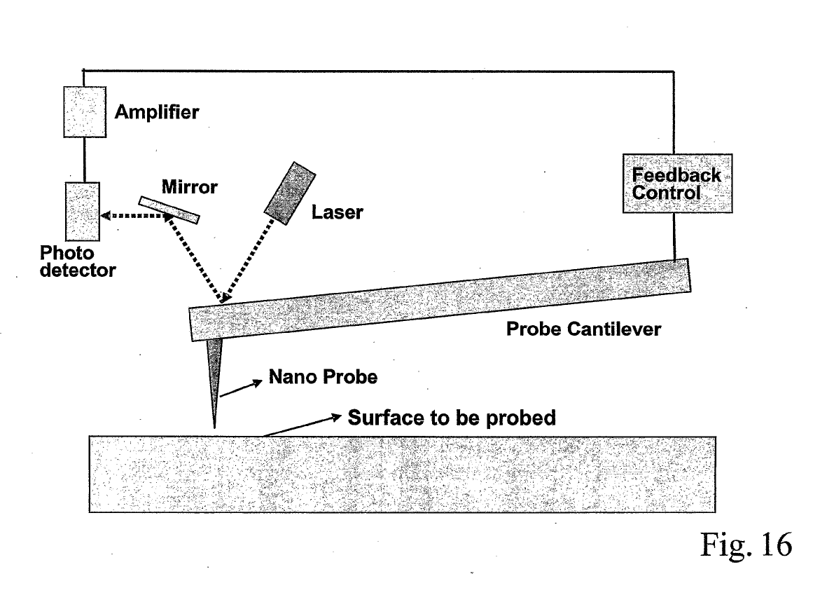

FIG. 16 schematically illustrates an AFM probe according to the invention which is capable of performing surface measurement functions with a metrology probe, mechanical tester probe, conductance probe, nanowriting probe, capacitance probe, magnetic probe, sidewall probe or wet environment surface analysis, using vertical, tilted or curved probe configuration relative to the probe cantilever.

### INDUSTRIAL APPLICABILITY

### AFM Systems Incorporating the Invention Probes

The sharp AFM probe described in this invention is useful for a variety of surface analysis in addition to the metrology analysis. For example, surface conductance measurements, mechanical property measurements, capacitance measurements, magnetic property measurements (e.g., with the nanocone probes coated with a magnetic material), sidewall property measurements (using a bent nanocone or bent nanotube probe), capacitance measurements, wet environment metrology or conductance measurements such as in bio imaging or electrochemical processing can be carried out, simultaneously as the metrology measurements. Such a versatile measurement capability is schematically illustrated in FIG. 16. The AFM probe positioning and sensing are carried out using the known laser control and feedback system.

It is understood that the above-described embodiments are illustrative of only a few of the many possible specific embodiments which can represent applications of the invention. Numerous and varied other arrangements can be made by those skilled in the art without departing from the spirit and scope of the invention.

### SUMMARY OF THE INVENTION

The invention and various embodiments disclosed in this patent application include the following groups of A-F. These probes are useful for a variety of AFM related system applications including surface probe measurements of metrology, conductance, capacitance, magnetic properties, mechanical peoperties, capacitance properties, sidewall probing, wet environment surface characterizations, and so forth.

A1. An AFM probe tip structure comprising an orientation-controlled (vertical or inclined), high-aspect-ratio nanocone structure without catalyst particles, with a tip radius of curvature of at most 20 nm, preferably at most 10 nm, even more preferably at most 5 nm. The desired nanocone aspect ratio is at least 3, preferably at least 5, even more preferably at least 10.

A2. The method of fabricating such a nanocone AFM probe structure incorporates relatively high applied electric field, in either vertical or inclined orientation during CVD growth. The desired electric field is at least 500 volts, preferably at least 550 volts. For inclined orientation of nanocones, a preferred method of applying an orienting electric field is to utilize the tilted local-surface electric fields from the recessed edges or recessed corners of the conductor plates in contact.

A3. Such a high-aspect-ratio, sharp nanocone probe tip provides sharper AFM metrology images or conductance measurements than the standard, uniform-diameter nanotube probes. Such a feature is beneficial for higher resolution analysis and for probing shallow crevices or narrow tracks. The improved resolution is by a factor of at least two as compared with a uniform-diameter nanotube probe tip having an identical volume.

A4. The probe base of the nanocone AFM probe is mechanically much more stable than the standard, uniform-diameter nanotube probes. The mechanical stability as indicated by the mechanical stiffness of the nanocone base is at least by a factor of two improved as compared with a uniform-diameter nanotube probe tip having an identical volume.

A5. A further improved version of the nanocone AFM probe structure allows an efficient nanoscale conductance measurement by also comprising an insulating surface coating of at least 2 nm, preferably at least 5 nm thickness.

A6. Another further improved version of the nanocone AFM probe structure comprises an array of at least two, preferably at least 5 spaced-apart probes for simultaneous measurements of electrical conductance at multiple locations, including ion conductance measurements on human, animal, or artificial cells.

A7. The nanocone AFM probe structure can optionally be fabricated by a large scale wafer processing and subsequently cut into many probes.

A8. The nanotube sidewall insulating surface coating in A1-A7 structure utilizing a physical or chemical vapor deposition, or electrochemical/chemical deposition of e.g., Al2O3, SiO2, Si3N4, TiO2, or plasma CVD deposition of SiO2, or a thin polymer coating, e.g., deposited by evaporation of monomer or polymer material onto the nanotube surface.

A9. The method of removing the insulator from the tip of the insulator-coated nanotube for conductance measurement, by utilizing mechanical abrasion or chemical etching.

A10. The method of depositing the thin insulator onto the nanotube sidewall without covering the very tip of nanotube by utilizing oblique-incident evaporation or sputtering from below the tip of the nanotube.

B1. An AFM probe tip structure comprising a sharply bent nanotube with a bending angle of at least 5 degrees, preferably at least 20 degrees. The inventive probe structure has a well-defined, sharp bending with a bending radius of curvature of less than 100 nm, preferably less than 40 nm. The preferred mode of fabricating the sharply bent nanotube AFM tip is the use of the CVD growth technique utilizing a carbon source and a DC plasma environment, and utilizing a tilted local-surface electric field from the recessed edges or recessed corners of the conductor plates in contact.

B2. A preferred method of fabricating the sharply-bent nanotube AFM probe structure includes the step of first mechanically attaching a desired length of a pre-made nanotube as a first leg of the bent nanotube probe, such as by arc welding, carbon deposition, or solder/braze bonding onto AFM pyramid, enhancing the adhesion of the nanotube onto the pyramid wall by thin film deposition (with the adhesion-enhancing metal film selected from Cr, Ti, Si, Mo, Zr, Hf, Nb, Ta, W, or their alloys), and then the use of a CVD growth process to nucleate and grow the second leg of the nanotube in a sharply bent orientation of at least 5 degrees, preferably at least 20 degrees from the direction of the first leg segment nanotube. The use of relatively high applied electric field, in either vertical or inclined orientation during CVD growth for the second segment of nanotube growth on top of the first leg nanotube is preferred. The desired electric field is at least 500 volts, preferably at least 550 volts. For inclined orientatioin of nanotubes, a preferred method of applying an orienting electric field is to utilize the tilted local-surface electric fields from the recessed edges or recessed corners of the conductor plates in contact.

B3. Another embodiment of the bent nanotube probe structure consists of a first segment nanotube with a uniform-diameter, at the end of which a second segment of a sharply bent nanotube or nanocone is added by CVD growth. The desired bending angle is at least 5 degrees and preferably at least 20 degrees, with the bending radius of curvature of less than 100 nm, preferably less than 40 nm. The bent second nanotube or nanocone preferably has a tapered structure with no catalyst particles left at the end.

B4. Yet another embodiment of the bent nanotube probe structure consists of a first segment which is a nanocone with a gradually tapering diameter, at the end of which a second segment of a sharply bent nanocone is added by CVD growth. The desired bending angle is at least 5 degrees and preferably at least 20 degrees, with the bending radius of curvature of less than 100 nm, preferably less than 40 nm. The bent second nanocone preferably has no catalyst particles left at the end.

B5. Such sharp bending of a nanotube or a nanocone in B3 or B4 is preferably obtained by high voltage DC plasma CVD, with the desired electric field applied is at least 500 volts, preferably at least 550 volts. For nanotube or nanocone bending, a preferred method of applying the orienting electric field is to utilize the tilted local-surface electric fields from the recessed edges or recessed corners of the conductor plates in contact.

B6. A further improved version of the inventive sharply-bent nanotube or nanocone AFM probe structure allows an efficient nanoscale conductance measurement by also comprising an insulating surface coating of at least 2 nm, preferably at least 5 nm thickness.

B7. Another further improved version of the inventive sharply-bent nanotube or nanocone AFM probe structure comprises an array of at least two, preferably at least 5 spaced-apart probes for simultaneous measurements of electrical conductance at multiple locations, including ion conductance measurements on human, animal, or artificial cells.

B8. The nanotube sidewall insulating surface coating in B1-B7 structure utilizing a physical or chemical vapor deposition, or electrochemical/chemical deposition of e.g., Al2O3, SiO2, Si3N4, TiO2, or plasma CVD deposition of SiO2, or a thin polymer coating, e.g., deposited by evaporation of monomer or polymer material onto the nanotube surface.

B9. The method of removing the insulator from the tip of the insulator-coated nanotube for conductance measurement, by utilizing mechanical abrasion or chemical etching.

B10. The method of depositing the thin insulator onto the nanotube sidewall without covering the very tip of nanotube by utilizing oblique-incident evaporation or sputtering from below the height of nanotube.

C1. An AFM probe tip structure comprising a two-stage, vertically hierarchic, nanotube structure to provide a high spatial resolution in combination with mechanical stability, obtained by a two-step CVD approach. The two-stage hierarchic nanotube structure consists of a larger-sized, mechanically sturdier nanocone base and a small-sized, much thinner, compliant nanotube probe CVD grown at the apex of the larger nanocone base.

C2. Such a vertically hierarchic nanotube structure is desirably fabricated by using a two-step CVD processing of first forming a nanocone base, but with a small-sized catalyst particle left for a second step CVD growth so as to form a smaller-diameter nanotube. The small-sized nanotube desirably has a diameter of at most 20 nm, preferably at most 10 nm, even more preferably at most 5 nm.

C3. The use of a relatively high applied electric field, in either vertical or inclined orientation during CVD growth for the second segment of nanotube growth on top of the first leg nanotube is preferred. The desired electric field is at least 500 volts, preferably at least 550 volts. For inclined orientation of nanotubes, a preferred method of applying an orienting electric field is to utilize the tilted local-surface electric fields from the recessed edges or recessed corners of the conductor plates in contact.

D1. An AFM probe tip structure comprising a pre-made, larger-size base such as AFM pyramid of Si or Si nitride, pointed metal, or carbon nanocone, onto which a straight or oriented small-diameter nanotube is grown. The small-diameter nanotube is nucleated and grown by selected CVD growth from a single, tip-only-exposed catalyst which is obtained by first depositing a multilayer thin film consisting of a catalyst layer and a non-catalyst layer, followed by removal of the non-catalyst material selectively leaving a small island size (e.g., at most 100 nm, preferably at most 50 nm, even more preferably at most 20 nm in diameter) at the very tip.

D2. The small-diameter nanotube desirably has a diameter of at most 20 nm, preferably at most 10 nm, even more preferably at most 5 nm.

D3. The use of relatively high applied electric field, in either vertical or inclined orientation during CVD growth for the small-diameter nanotube growth on top of the larger-size base is preferred. The desired electric field is at least 500 volts, preferably at least 550 volts. For inclined orientation of nanotubes, a preferred method of applying an orienting electric field is to utilize the tilted local-surface electric fields from the recessed edges or recessed corners of the conductor plates in contact.

E1. An AFM probe tip structure comprising a pre-made, larger-size base such as AFM pyramid of Si or Si nitride, pointed metal, or carbon nanocone, onto which a straight or oriented small-diameter nanotube is grown. The small-diameter nanotube is nucleated and grown by selected CVD growth from a single, tip-only-exposed catalyst which is obtained by dip coating of a catalyst-containing precursor material onto the tip of the larger-size base followed by thermal decomposition to form a small catalyst island that allows a growth of a single, small-diameter nanotube.

E2. The small-diameter nanotube desirably has a diameter of at most 20 nm, preferably at most 10 nm, even more preferably at most 5 nm.

E3. The use of relatively high applied electric field, in either vertical or inclined orientation during CVD growth for the small-diameter nanotube growth on top of the larger-size base is preferred. The desired electric field is at least 500 volts, preferably at least 550 volts. For inclined orientatioin of nanotubes, a preferred method of applying an orienting electric field is to utilize the tilted local-surface electric fields from the recessed edges or recessed corners of the conductor plates in contact.

F1. A further improved version of the inventive nanotube AFM probe configurations of C1-C3, D1-D3, E1-E3 which allows an efficient nanoscale conductance measurement by also comprising a sidewall insulating surface coating of at least 2 nm, preferably at least 5 nm thickness.

F2. Another further improved version of the inventive nanotube AFM probe configurations of F1 which also comprise an array of at least two, preferably at least 5 spaced-apart probes for simultaneous measurements of electrical conductance at multiple locations, including ion conductance measurements on human, animal, or artificial cells.

F3. The sidewall insulating surface coating in F1 which is deposited utilizing a physical or chemical vapor deposition, or electrochemical/chemical deposition of e.g., Al2O3, SiO2, Si3N4, TiO2, or plasma CVD deposition of SiO2, or a thin polymer coating, e.g., deposited by evaporation of monomer or polymer material onto the nanotube surface.

F4. The method of removing the insulator from the tip of the insulator-coated nanotube for conductance measurement, by utilizing mechanical abrasion or chemical etching.

F5. The method of depositing the thin insulator onto the nanotube sidewall without covering the very tip of nanotube by utilizing oblique-incident evaporation or sputtering from below the height of nanotube.

Having described the invention, we claim:

1. A carbon nanocone based nanoprobe structure having a length to base diameter aspect ratio of at least 3 or more, in which the nanocone is in a CVD grown, electrical-field-guided, aligned configuration.

2. An atomic force microscopy nanoprobe comprising a hierarchic configuration of carbon nanocone base and a smaller diameter nanoprobe tip wherein the length to base diameter aspect ratio is at least 3 or more.

3. The nanoprobe structure of claims 1 or 2 wherein the length to base diameter aspect ratio is at least 10 or more.

4. The nanoprobe structure of claims 1 or 2 further comprising an insulating surface coating of at least 2 nanometers.

5. The nanoprobe structure of claims 1 or 2 further comprising a thin coating of electrically conductive film with a thickness of at least 1 nanometer, with the conductive coating selected from a metallic alloy, carbide, nitride or oxide material.

6. The nanoprobe structure of claims 1 or 2 comprising a plurality of spaced apart nanoprobes on a single cantilever surface.

7. The nanoprobe structure of claim 4 or 5 where the insulating surface coating comprises a member from the group consisting of Al₂O₃, SiO₂, Si₃N₄, TiO₂ and a thin polymer.

8. The nanoprobe structure of claim 7 wherein the insulating surface coating is applied by the use of chemical vapor deposition or evaporation of a polymer material onto the nanoprobe surface.

9. A method of fabricating a laser-controllable nanocone probe structure comprising chemical vapor deposition on a substrate in the presence of an electric field of at least 500 volts.

10. A method of removing insulation from the tip only of the nanoprobe structure of claim 4 comprising mechanical abrasion or chemical etching.

11. A method of depositing insulation onto the nanoprobe structure of claim 5 comprising oblique-incident evaporation or sputtering from below the tip of the nanotube.

12. An atomic force microscopy nanoprobe structure having a sharply bent nanotube tip with a bending angle of at least 5 degrees and with a bending radius of curvature of less than 100 nm.

13. The nanoprobe structure of claims 12 wherein the electric field guided growth of a bent nanotube or nanocone is carried out in a recessed corner of conductors in contact.

14. The nanoprobe structure of claim 12 in which the nanoprobe structure comprises a first segment nanotube with a uniform diameter, at the end of which is a sharply bent second segment nanotube or nanocone.

15. The nanoprobe structure of claim 12 in which the nanoprobe structure comprises a first segment nanocone with a gradually tapering diameter, at the end of which is a sharply bent second segment nanotube or nanocone.

16. The nanoprobe structure of claim 12 further comprising an insulating surface coating of at least 5 nanometers.

17. A method of manufacturing an atomic force microscopy nanoprobe comprising a nanocone base and a nanoprobe tip, comprising a two step chemical vapor deposition process of first forming a nanocone base with a small sized catalyst particle retained at the top of the nanocone base, a second step chemical vapor deposition process to form a nanotube at the top of the nanocone base, having a smaller diameter than the nanocone base.

18. The method of claim 17 in which the second step takes place in the presence of a vertical or inclined electric field of at least 500 volts.

19. A method of manufacturing an atomic force microscopy nanoprobe comprising a silicon or silicon nitride pyramid base and a nanoprobe tip, comprising a two step process of first forming a pyramid base, depositing a catalyst layer over the pyramid base, depositing a non-catalyst layer over the catalyst layer, selectively removing a small portion of the non-catalyst layer at the top of the pyramid base leaving a small sized catalyst island exposed at the top of the pyramid base, a second step of chemical vapor deposition process to form a nanotube at the top of the pyramid base, having a smaller diameter than the pyramid base.

20. The method of claim 19 in which the second step takes place in the presence of a vertical or inclined electric field of at least 500 volts.

21. A method of manufacturing an atomic force microscopy sharply bent nanoprobe comprising mechanically attaching a length of a pre-made nanotube to a pyramid wall as a first leg, enhancing the adhesion of the nanotube to the pyramid wall by thin film deposition, using a chemical vapor deposition process, in the presence of an electric field of at least 500 volts, to grow a second nanotube leg in a sharply bent orientation from the direction of the first leg.

22. The method of claim 21 in which mechanical attachment is done by arc welding, carbon deposition, or solder braze bonding.

23. The method of claim 21 in which the thin film deposited, adhesion enhancement material is selected from a group consisting of Cr, Ti, Si, Mo, Zr, Hf, Nb, Ta, W, or their alloys.

24. The method of claim 21 in which the second leg is formed in the presence of a tilted electric field.

25. A nonocone structure comprising a first nonocone having a base and a tip, a second nanocone grown from the tip of the first nanocone, wherein the aspect ratio of the length to the base of the second nanocone is at least 3 times larger than the aspect ratio of the first nanocone.

26. A nonocone structure comprising a first nonocone having a base and a tip, a second nanocone grown from the tip of the first nanocone, wherein the second nanocone is bent from the first nanocone by at least 10 degrees.

27. The nonocone structure of claim 26 further comprising a catalyst particle at the tip of the second nanocone.

28. An atomic force microscopy surface analysis device comprising the nanoprobe of claims 1, 2 or 12, used for a metrology probing system, a conductance probing system, a surface capacitance measurement system, a surface field emission or work function measurement system, a surface mechanical property measurement system, a surface magnetic measurement system, a surface local work function measurement system, a sidewall metrology and conductance measurement system, or a wet environment measurement system.
